(19) United States
(12) Patent Application Publication
(10) Pub. No.: US 2021/0088896 A1
(43) Pub. Date: Mar. 25, 2021

(54) LITHOGRAPHY SIMULATION AND OPTICAL PROXIMITY CORRECTION

(71) Applicant: Applied Materials, Inc., Santa Clara, CA (US)

(72) Inventors: Huixiong DAI, San Jose, CA (US); Mangesh Ashok BANGAR, San Jose, CA (US); Pinkesh Rohit SHAH, San Jose, CA (US); Srinivas D. NEMANI, Sunnyvale, CA (US); Steven Hiloong WELCH, Milpitas, CA (US); Christopher Siu Wing NGAI, Burlingame, CA (US); Ellie Y. YIEH, San Jose, CA (US)

(21) Appl. No.: 16/983,093

(22) Filed: Aug. 3, 2020

Related U.S. Application Data
(60) Provisional application No. 62/904,082, filed on Sep. 23, 2019.

(51) Int. Cl. G03F 1/36; G03F 7/38

(52) U.S. Cl. CPC G03F 1/36; G03F 7/38

(57) ABSTRACT

Embodiments of the disclosure relate to lithography simulation and optical proximity correction. Field-guided post exposure bake processes have enabled improved lithography performance and various parameters of such processes are included in the optical proximity correction models generated in accordance with the embodiments described herein. An optical proximity correction model includes one or more parameters of anisotropic acid etching characteristics, ion generation and/or movement, electron movement, hole movement, and chemical reaction characteristics.

### CROSS-REFERENCE TO RELATED APPLICATIONS

This application claims benefit of U.S. Provisional Patent Application No. 62/904,082, filed Sep. 23, 2019, the entirety of which is herein incorporated by reference.

### BACKGROUND

### Field

Embodiments of the present disclosure generally relate to lithography simulation and optical proximity correction. More specifically, embodiments of the disclosure relate to field-guided post exposure bake optical proximity correction models, lithography simulation incorporating the same, and mask tape out techniques.

### Description of the Related Art

Semiconductor devices are manufactured by depositing many different types of material layers over a semiconductor substrate and patterning the various material layers using lithography. The material layers typically include thin films of conductive, semi-conductive, and insulating materials that are patterned and etched to form integrated circuits. Lithography involves transferring an image of a mask to a material layer of the substrate. The image is formed in a layer of photoresist, the photoresist is developed, and the photoresist is used as a mask during a process to alter the material layer, such as etching and patterning the material layer.

As feature sizes of semiconductor devices continue to decrease, transferring patterns from a lithography mask to a material layer on a substrate becomes increasingly difficult due to the effects of the light or energy used to expose the photoresist. A phenomenon commonly referred to as the proximity effect results in the variation of line widths. For example, closely-spaced features tend to be smaller than widely spaced features even though such features are the same dimension on a lithography mask. Such variation in line width may result in undesirable patterning and device fabrication.

To compensate for the proximity effect, optical proximity correction (OPC) is often made to lithography masks, which may involve adjusting the widths or lengths of the lines, corner rounding, and the addition of serifs to enhance the ultimate patterning performance of the mask. OPC modeling is utilized to improve lithography masks and reduce the amount of time associated with mask design. Conventional OPC modeling typically utilizes known parameters to create a model which can then be implemented to improve mask design. However, when new lithography and patterning techniques are developed, conventional OPC modeling processes are insufficient because such processes do not contemplate advances derived from improved lithography and patterning techniques.

Thus, there is a need in the art for improved lithography simulation and optical proximity correction.

### SUMMARY

In one embodiment, an optical proximity correction method is provided. The method includes receiving input of a mask design layout into an optical proximity correction tool and performing a mask design layout simulation using field-guided post-exposure bake parameters. An optical proximity correction model is then generated based at least partially upon the field-guided post-exposure bake parameters.

In another embodiment, a substrate processing method is provided. The method includes receiving input of a mask design layout into an optical proximity correction tool, performing a mask design layout simulation using field-guided post-exposure bake parameters, generating an optical proximity correction model based at least partially upon the field-guided post-exposure bake parameters, and patterning a substrate using a lithography apparatus comprising a mask.

In another embodiment, a substrate processing method is provided. The method includes receiving input of a mask design layout into an optical proximity correction tool, performing a mask design layout simulation using field-guided post-exposure bake parameters, generating an optical proximity correction model based at least partially upon the field-guided post-exposure bake parameters, patterning a substrate after adjusting the mask design layout based upon the optical proximity correction model, and performing a field-guided post-exposure bake process on the substrate after patterning the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 schematically illustrates a lithography system for patterning a material layer of a semiconductor device according to an embodiment described herein.

FIG. 2 illustrates a block diagram of an optical proximity correction tool used to determine optical proximity corrections in accordance with an embodiment described herein.

FIG. 3 illustrates operations of a method for developing an optical proximity correction model according to an embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure relate to lithography simulation and optical proximity correction. Field-guided post exposure bake processes have enabled improved lithography performance and various parameters of such processes are included in the optical proximity correction models generated in accordance with the embodiments described herein. An optical proximity correction model includes one or more parameters of anisotropic acid etching characteristics, ion generation and/or movement, electron movement, hole movement, and chemical reaction characteristics.

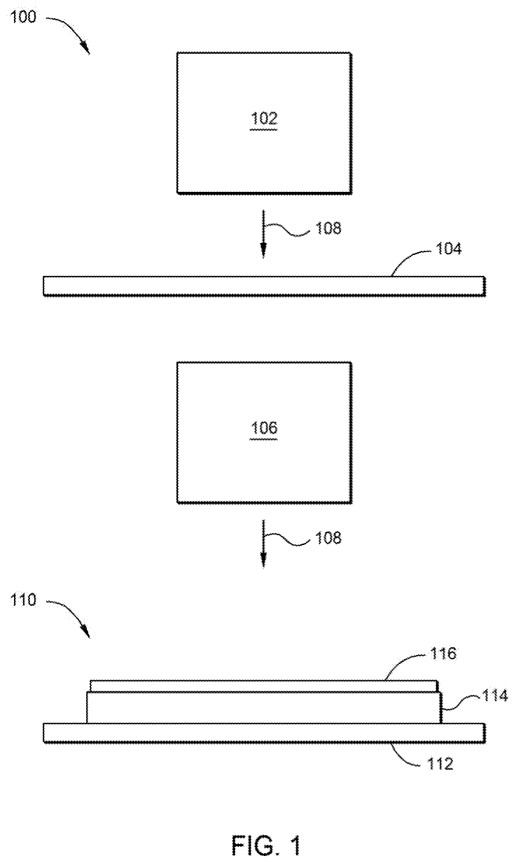

FIG. 1 schematically illustrates a lithography system 100 for patterning a material layer of a semiconductor device 110 according to an embodiment described herein. The lithography system 100 includes an illuminator 102 and a lens system 106. For example, the lithography system 100 may be a 193 nm lithography system, an extreme ultra-violet lithography system, or other lithography system configured to pattern a substrate. A lithography mask 104 is disposed between the illuminator 102 and the lens system 106. A semiconductor device 110 is patterned by disposing a layer of photosensitive material 116 over a substrate 114, positioning the semiconductor device 110 on a support 112, and directing light or energy 108 from the illuminator 102 through the mask 104 and lens system 106 towards the semiconductor device 110.

A pattern from the lithography mask 104 is transferred to the layer of photosensitive material 116 on the substrate 114. In one embodiment, the photosensitive material 116 is a photoresist material which includes a photoacid generator. The layer of photosensitive material 116 is developed and then the layer of photosensitive material 234 is used as a mask while the substrate 114 is patterned or etched. In one embodiment, deprotection and/or development of the photosensitive material 116 is performed utilizing a field-guided post-exposure bake process. Similarly, photosensitive material deprotection and/or development may be performed utilizing an immersion field-guided post-exposure bake process. In such an embodiment, a fluid, such as a liquid, is utilized to couple an electric field to the photosensitive material 116 to improve deprotection and/or development characteristics of the photosensitive material 116.

Methods disclosed herein apply an electric field to the substrate 114 on which the photosensitive material 116 is disposed during a post-exposure bake operation of a lithography processes. Application of the electric field controls the diffusion and distribution of the acids generated by the photosensitive material 116 (photoacid generator) to improve resist deprotection characteristics of the resist which enables improved patterning of the substrate. By application of the electric field, acid, which may be ionized, is directed substantially perpendicular to a major axis of the substrate to provide for anisotropic deprotection. Such anisotropic deprotection results in the pattern formed by the photosensitive material 116 having improved line verticality and more desirable critical dimensions.

In one example, the post-exposure bake procedure is performed after an exposure operation of a photolithography process, in which the photosensitive material 116 on the substrate 114 is exposed to electromagnetic radiation from the illuminator 102. The photosensitive material 116 is formed on the substrate 114 and includes a resist resin and a photoacid generator. The mask 104 is used to selectively expose the photosensitive material 116 to electromagnetic radiation. Exposure of portions of the photosensitive material 116 through openings in the mask causes a latent pattern to form in the photosensitive material 116, where the layout of the latent pattern is dependent on the layout of the mask. The latent pattern is characterized by a change in the chemical properties of the photosensitive material 116 such that subsequent processing can selectively remove desired portions of the photosensitive material 116. For example, the photoacid generated as a result of the exposure functions to solvate the photosensitive material 116 which are removed during a subsequent photoresist removal process.

A post-exposure bake process performed after the exposure operation includes application of heat to the photosensitive material 116. The application of heat causes further changes to the chemical properties of the photosensitive material 116 such that a subsequent development operation will selectively remove desired portions of the photoresist.

The substrate 114 on which the photosensitive material 116 is disposed may be any suitable type of substrate, such as a dielectric substrate, a glass substrate, a semiconductor substrate, a conductive substrate, or the like. The substrate 114 has one or more material layers disposed thereon. The material layers may be any desired layer, such as a semiconducting material, or an oxide material, among others. The substrate 114 also has the photosensitive material 116 disposed over the one or more material layers. When the post-exposure bake process is performed, the substrate 114 has been previously exposed to electromagnetic radiation in an exposure operation of a photolithography process. As a result, the photosensitive material 116 has latent image lines which define a latent image of the electromagnetically-altered photoresist.

By applying the electric field described above to the photosensitive material 116 during the post-exposure bake process, distribution of photoacid in exposed regions of the photosensitive material 116 is efficiently controlled and confined. The electric field applied to the photosensitive material 116 moves photoacid in a direction parallel or perpendicular to the latent image lines to better and more completely solvate exposed regions of the photosensitive material 116. As such, the photoacid generally does not diffuse into adjacent non-exposed regions. Generally, photoacid has a certain polarity that may be affected by an electric field applied thereto. Such an applied electric field will orient photoacid molecules in directions that are in accordance with the electric field. When such electric field is applied, the photoacid moves in a desired direction such that the photoacid may contact and solvate the photosensitive material 116 in an anisotropic manner. Consequently, such a deprotection process improves the anisotropic nature of the photosensitive material removal. With improved verticality of exposed regions, pattern transfer to the underlying substrate 114 is improved and critical dimensions are more accurately transferred from the mask 104 to the substrate 114.

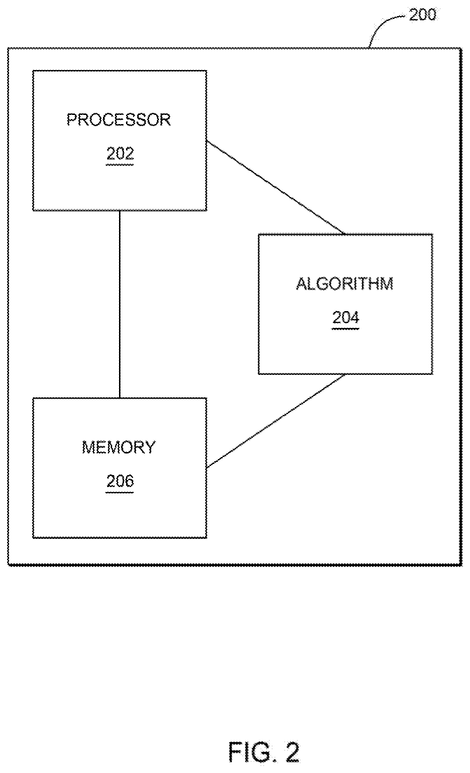

FIG. 2 illustrates a block diagram of an optical proximity correction (OPC) tool 200 used to determine optical proximity corrections in accordance with an embodiment described herein. The OPC tool 200 includes an algorithm 204 adapted to perform OPC with improved parameters derived from a field guided post-exposure bake process or an immersion field-guided post-exposure bake process. The OPC tool 200 includes a memory 206 or storage adapted to store a lithography mask design layout and OPC calculations. The OPC tool 200 also includes a processor 202 adapted to perform OPC calculations and make comparisons of calculated images with target feature designs. The OPC tool 200 may also include other subsystems and devices, such as operator interface equipment and the like. In one embodiment, the memory 206 stores the layout or mask design. It is contemplated that the mask design layout is embodied in the form of a data file or the like for storage in the memory 206. The algorithm 204 determines optical proximity corrections for the layout or mask design and the processor 202 performs optical proximity correction calculation in accordance with the algorithm 204 and adjusts the layout or mask design in accordance with the optical proximity corrections determined. In another embodiment, the OPC tool 200 is utilized to generate an OPC model which is utilized to adjust the mask design layout.

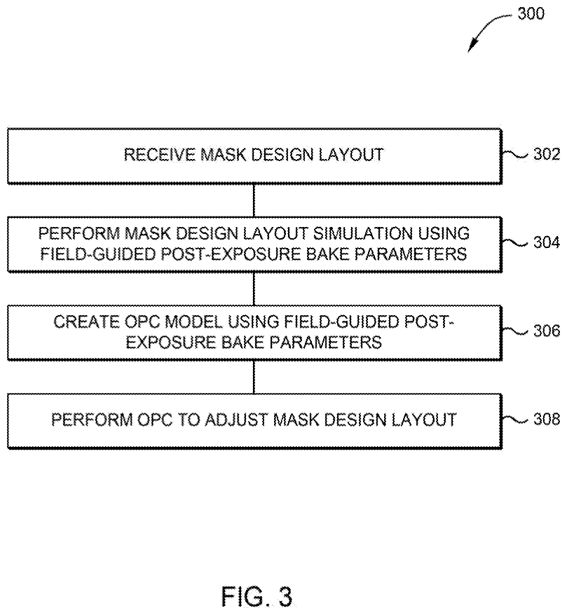

FIG. 3 illustrates operations of a method 300 for developing an optical proximity correction model according to an embodiment of the disclosure. At operation 302, a mask design layout is received. For example, the mask design layout is received or otherwise input into the OPC tool 200 and stored in the memory 206. At operation 304, a mask design layout simulation is performed using field-guided post-exposure bake parameters. In other words, a patterning simulation is performed to determine patterning performance when the mask design layout is utilized with an advanced development technique, such as a field-guided post-exposure bake process.

At operation 306, an OPC model is created using the field-guided post-exposure bake parameters. Field-guided post-exposure bake parameters which are input to calculate and create the OPC model include, but are not limited to anisotropic acid etching characteristics, ion generation and/or movement characteristics, electron movement characteristics, hole movement characteristics, and chemical reaction characteristics. In other words, such characteristics are indicative of the photosensitive material behavior when the photosensitive material is subjected to a filed-guided post-exposure bake process.

Other parameters which are input to calculate and create the OPC model include parameters of the lithography apparatus, such as the type and dosage of electromagnetic energy utilized to pattern the photosensitive material and various lens parameters, for example, optical characteristics of the lens and the like. Additional parameters input to calculate and create the OPC model include the types of films to be patterned, including the type of photosensitive material, layer stacks to be etched, the presence of antireflective coatings, and various optical conditions of any of the aforementioned films. Further parameters input to calculate and create the OPC model include the type and material of mask utilized to pattern the substrate.

It is believed that utilizing a field-guided post-exposure bake process causes the formation of excess acid resulting from an electrochemical reaction upon exposure of the photosensitive material to electromagnetic radiation. The electrochemical reaction results in electron and hole formation which enables decomposition of the photosensitive material by release of acid (H⁺). The acid is then guided by an electric field to improve photosensitive material deprotection. Such improvement results in improved critical dimensions between adjacent lines due to the anisotropic deprotection afforded by application of the electric field in a desired direction. Electromagnetic radiation dosage sensitivity of the photosensitive material is also improved because of the additional deprotection control enabled by application of the electric field during the field-guided post-exposure bake process.

At operation 308, OPC is performed to adjust the mask design layout. The results of the OPC simulation are then utilized as feedback to improve the mask design layout to achieve a more accurate representation of actual on-substrate patterning characteristics. In certain embodiments, the mask design layout is altered in response to the information obtained in operation 308. Thus, the OPC model generated in accordance with the embodiments described herein enables improved patterning performance with advanced development techniques, such as field-guided post-exposure bake processes.

For example, the OPC models enable dosage reduction which reduces the potential for over exposure of photosensitive material and may provide for improved pattern transfer fidelity from the mask to the substrate. In one example, comparable contact hole size critical dimensions are achieved utilizing the method 300 with a dosage which is reduced from a conventional exposure process. In this example, a contact hole size critical dimension of approximately 21 nm was fabricated utilizing a dosage of approximately 37 mJ/cm² in a conventional exposure process. A contact hole size critical dimension of approximately 21 nm was fabricated utilizing a dosage of approximately 27 mJ/cm² by implementing one or more of the embodiments described herein. Thus, an exposure dosage reduction of between about 25% and about 35% may be achieved which is believed to provide improved pattern transfer fidelity and improve contact hole morphological characteristics.

In another embodiment, the OPC models enable improved mask error enhancement factor simulations. In one example, a conventional process utilizing a mask with an approximately 28 nm contact hole critical dimension can form a contact hole on a substrate with an approximately 12 nm critical dimension. Thus, the conventional process has an approximately 16 nm difference between the mask critical dimension and the on-substrate critical dimension. By utilizing the embodiments described herein, a mask with an approximately 28 nm contact hole critical dimension produced a contact hole on the substrate with an approximately 20 nm critical dimension. The mask error between a conventional process and the processes described herein was reduced by approximately 50%. It is also believed that critical dimension linearity among various critical dimensions is improved, thus enabling more consistent simulations with varying critical dimension and mask layout designs. Accordingly, mask error enhancement factor simulations may be improved as a result of the improved performance enabled by the embodiments of the disclosure.

Critical dimensions between adjacent features are also improved due to the anisotropic deprotection characteristics which enable mask layout designs to further increase the density of features and improve the resolution of patterns transferred from a mask to a substrate. In one embodiment, the critical dimensions between adjacent features are increased. Further, it is contemplated that mask error effects are improved by the OPC models which include input parameters for field-guided post-exposure bake development processes.

Further advantages of OPC models generated according to the embodiments described herein include improved model calibration, improved generation of simulated resist image contours, and improved calculation of critical dimensions and/or edge placement errors. The OPC models described herein are also utilized to determine the magnitude of OPC for a given reticle used to produce a desire feature pattern for a given mask layout design. Further, it is contemplated that the OPC models of this disclosure may be implemented to improve source mask optimization simulation for process optimization, OPC, mask design layout, and mask error enhancement factor processes. It is further contemplated that the embodiments of this disclosure reduce image blurring.

While the foregoing is directed to embodiments of the present disclosure, other and further embodiments of the disclosure may be devised without departing from the basic scope thereof, and the scope thereof is determined by the claims that follow.

What is claimed is:

1. An optical proximity correction method, comprising:
receiving input of a mask design layout into an optical proximity correction tool;
performing a mask design layout simulation using field-guided post-exposure bake parameters; and
generating an optical proximity correction model based at least partially upon the field-guided post-exposure bake parameters.

2. The method of claim 1, wherein the field-guided post-exposure bake parameters comprise one or more of anisotropic acid etching characteristics, ion generation and/or movement characteristics, electron movement characteristics, hole movement characteristics, and chemical reaction characteristics.

3. The method of claim 1, wherein the optical proximity correction tool comprises:
a processor; and
a memory configured to store a lithography mask design layout.

4. The method of claim 3, wherein the lithography mask design layout is a data file.

5. The method of claim 1, further comprising:
generating the optical proximity correction model based upon one or more parameters of a lithography apparatus.

6. The method of claim 5, wherein the one or more parameters of the lithography apparatus comprise a type and dosage of electromagnetic energy and optical lens parameters.

7. The method of claim 1, further comprising:
generating the optical proximity correction model based upon one or more parameters of the substrate.

8. The method of claim 7, wherein the one or more parameters of the substrate comprise a type of film to be patterned, layer stacks to be etched, and the presence of one or more antireflective coatings.

9. The method of claim 8, wherein the one or more parameters of the substrate comprise optical characteristics of one or more or the type of film to be patterned, the layer stacks to be etched, and the one or more antireflective coatings.

10. The method of claim 1, further comprising:
generating the optical proximity correction model based upon the type and material of a mask utilized to pattern the substrate.

11. The method of claim 1, further comprising:
performing an optical proximity correction process to adjust the mask design layout.

12. The method of claim 11, further comprising:
altering the mask design layout is response to performing the optical proximity correction process.

13. The method of claim 11, further comprising:
altering a mask error enhancement factor in response to performing the optical proximity correction process.

14. A substrate processing method, comprising:
receiving input of a mask design layout into an optical proximity correction tool;
performing a mask design layout simulation using field-guided post-exposure bake parameters;
generating an optical proximity correction model based at least partially upon the field-guided post-exposure bake parameters; and
patterning a substrate using a lithography apparatus comprising a mask.

15. The method of claim 14, wherein the field-guided post-exposure bake parameters comprise one or more of anisotropic acid etching characteristics, ion generation and/or movement characteristics, electron movement characteristics, hole movement characteristics, and chemical reaction characteristics.

16. The method of claim 14, further comprising:
generating the optical proximity correction model based upon the type and material of the mask utilized to pattern the substrate.

17. The method of claim 14, further comprising:
performing an optical proximity correction process to adjust the mask design layout.

18. The method of claim 17, further comprising:
altering the mask design layout is response to performing the optical proximity correction process.

19. The method of claim 17, further comprising:
altering a mask error enhancement factor in response to performing the optical proximity correction process.

20. A substrate processing method, comprising:
receiving input of a mask design layout into an optical proximity correction tool;
performing a mask design layout simulation using field-guided post-exposure bake parameters;
generating an optical proximity correction model based at least partially upon the field-guided post-exposure bake parameters;
patterning a substrate after adjusting the mask design layout based upon the optical proximity correct model; and
performing a field-guided post-exposure bake process on the substrate after patterning the substrate.
